(19) United States
(12) Patent Application Publication
(10) Pub. No.: US 2026/0314097 A1
(43) Pub. Date: Oct. 8, 2026

(54) IMAGE SENSING DEVICE

(71) Applicant: SK hynix Inc., Icheon-si (KR)

(72) Inventor: Woo Yung JUNG, Icheon-si (KR)

(21) Appl. No.: 19/332,998

(22) Filed: Sep. 18, 2025

(30) Foreign Application Priority Data
Apr. 2, 2025 (KR) 10-2025-0042774

(51) Int. Cl. H10F 39/00

(52) U.S. Cl. CPC H10F 39/8063; H10F 39/8053; H10F 39/811

(57) ABSTRACT

Image sensing devices are disclosed. In an embodiment, an image sensing device includes an active pixel region; and a peripheral region. The peripheral region is disposed adjacent to at least one side of the active pixel region, and includes a light-scattering suppression layer, a first base layer spaced apart from the light-scattering suppression layer, and a second base layer covering at least a portion of each of the light-scattering suppression layer and the first base layer.

### PRIORITY CLAIM AND CROSS-REFERENCE TO RELATED APPLICATION

This patent document claims the priority and benefits of Korean patent application No. 10-2025-0042774, filed on Apr. 02, 2025, the disclosure of which is incorporated herein by reference in its entirety as part of the disclosure of this patent document.

### TECHNICAL FIELD

The technology and implementations disclosed in this patent document generally relate to an image sensing device capable of generating image data by sensing light.

### BACKGROUND

An image sensing device can capture optical images by converting light into electrical signals using a photosensitive semiconductor material that reacts to light. With advancements in industries such as automotive, medical, computer and communication industries, the demand for high-performance image sensing devices is growing across various fields such as smartphones, digital cameras, game machines, IoT (Internet of Things), robots, security cameras and medical micro cameras.

The image sensing device may be roughly divided into charge coupled device (CCD) image sensing devices and complementary metal oxide semiconductor (CMOS) image sensing devices. CCD image sensing devices offer a better image quality, but they tend to consume more power and are larger as compared to CMOS image sensing devices. CMOS image sensing devices are smaller in size and consume less power than CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device with improved processability or enhanced productivity.

In an embodiment of the disclosed technology, a semiconductor device may include: an active pixel region including a photoelectric conversion region configured to convert incident light into electrical signals; and a peripheral region disposed adjacent to at least one side of the active pixel region, and including a light scattering suppression layer that reduces scattering of light, a first base layer spaced apart from the light scattering suppression layer, and a second base layer covering at least a portion of each of the light scattering suppression layer and the first base layer.

In some implementations, the second base layer may extend to the active pixel region. The image sensing device further includes a lens layer, wherein the lens layer includes a plurality of nanostructures spaced apart from each other on the second base layer of the active pixel region.

In some implementations, the lens layer may further include a dielectric layer disposed between the plurality of nanostructures.

In some implementations, the image sensing device may further include: a semiconductor layer disposed below the light scattering suppression layer and the first base layer in the peripheral region, and including the photoelectric conversion region in the active pixel region; and a light blocking layer disposed on at least a portion of the semiconductor layer, and including a first portion and a second portion. The first portion may be disposed below the light-scattering suppression layer; and the second portion may be disposed below the first base layer.

In some implementations, the light blocking layer may include a third portion connecting the first portion to the second portion.

In some implementations, the third portion may be formed to contact the second base layer.

In some implementations, the second base layer may extend between the first base layer and the light-scattering suppression layer.

In some implementations, the peripheral region may further include: a light blocking region in which the light blocking layer is located; and a pad region disposed at one side of the light blocking region and including a pad configured to transmit and receive electrical signals, wherein the first base layer is disposed in each of the pad region and the light blocking region.

In some implementations, the second base may extend from the first base layer onto the light-scattering suppression layer; and the second base layer may include a first top surface having a first height and a second top surface having a second height different from the first height. The first top surface may overlap the light-scattering suppression layer in plan view; and the second top surface may overlap a space between the first base layer and the light-scattering suppression layer in plan view.

In some implementations, the second base layer may include a third top surface having a third height in a region overlapping the first base layer in plan view, wherein the third height is different from the second height.

In some implementations, at least one of the first base layer and the second base layer may include at least one of an epoxy resin, a polyurethane resin, a polyester resin, an acrylic resin, and a silicone resin.

In some implementations, the first base layer may include a different material from the second base layer.

In another embodiment of the disclosed technology, an image sensing device may include: an active pixel region including a first portion of a semiconductor layer that includes a photoelectric conversion region configured to convert incident light into electrical signals; and a peripheral region disposed adjacent to the active pixel region, and including a light scattering suppression layer disposed on a second portion of the semiconductor layer extending from the first portion of the semiconductor layer and a base layer covering at least a portion of the light scattering suppression layer, wherein the base layer includes a groove portion recessed toward a top surface of the semiconductor layer.

In some implementations, the groove portion may be located outside an edge portion of the light scattering suppression layer in plan view.

In some implementations, the groove portion may be formed in a line shape extending along an outer surface of the edge portion of the light-scattering suppression layer.

In some implementations, the base layer may include a first base layer spaced apart from the light-scattering suppression layer, and a second base layer disposed on the first base layer, wherein the second base layer includes a second base layer formed to cover at least a portion of the light-scattering suppression layer and the first base layer.

In some implementations, the peripheral region may include a pad region in which a pad configured to transmit and receive electrical signals is exposed from the semiconductor layer, and a light blocking region disposed between the pad region and the active pixel region, and a light blocking region disposed between the pad region and the active pixel region. The groove portion may be disposed in the light blocking region.

In some implementations, the peripheral region may include: a pad region where a pad configured to transmit and receive electrical signals is exposed from the semiconductor layer; a light blocking region disposed between the pad region and the active pixel region; and a margin region located outside the pad region, wherein the groove portion is disposed in the margin region.

In another embodiment of the disclosed technology, an image sensing device may include: a semiconductor layer including a photoelectric conversion region; a light-scattering suppression layer disposed on the semiconductor layer; a first base layer disposed on the semiconductor layer and spaced apart from the light-scattering suppression layer; and a second base layer configured to cover the light-scattering suppression layer and the first base layer. The second base layer may include: a first region formed to overlap the light-scattering suppression layer in plan view; a second region formed to overlap the first base layer in plan view; and a third region disposed between the first region and the second region, wherein the third region has a top surface recessed into the semiconductor layer.

In some implementations, the image sensing device may further include: a color filter layer disposed on the semiconductor layer, wherein the second base layer includes a region extending from the first region onto a top surface of the color filter layer.

It is to be understood that both the foregoing general description and the following detailed description of the disclosed technology are illustrative and explanatory and are intended to provide further explanation of the disclosed technology as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example of an image sensing device based on some embodiments of the disclosed technology.

FIG. 2 is a plan view illustrating a portion of the image sensing device shown in FIG. 1 based on some embodiments of the disclosed technology.

FIG. 3 is a cross-sectional view illustrating an example of the image sensing device taken along the line I-I’ shown in FIG. 2 based on some embodiments of the disclosed technology.

FIG. 4A is an enlarged cross-sectional view illustrating an example of the region (A) shown in FIG. 3 based on some embodiments of the disclosed technology.

FIG. 4B is an enlarged cross-sectional view illustrating an example of the region (B) shown in FIG. 3 based on some embodiments of the disclosed technology.

FIG. 5A is an enlarged cross-sectional view illustrating another example of the region (A) shown in FIG. 3 based on some embodiments of the disclosed technology.

FIG. 5B is an enlarged cross-sectional view illustrating an example of the region (B) shown in FIG. 3 based on some embodiments of the disclosed technology.

FIG. 6A is a cross-sectional view illustrating another example of the image sensing device taken along the line I-I’ shown in FIG. 2 based on some embodiments of the disclosed technology.

FIG. 6B is an enlarged cross-sectional view illustrating an example of the region (C) shown in FIG. 6A based on some embodiments of the disclosed technology.

FIGS. 7A-7E are cross-sectional views illustrating examples of a method for manufacturing the image sensing device based on some embodiments of the disclosed technology.

### DETAILED DESCRIPTION

This patent document provides implementations and examples of an image sensing device capable of generating image data by sensing light that may be used in configurations to substantially address one or more technical or engineering issues and to mitigate limitations or disadvantages encountered in some other image sensing devices. Some implementations of the disclosed technology relate to an image sensing device with improved processability or higher productivity. In recognition of the issues above, some embodiments of the disclosed technology provide an image sensing device that includes a first base layer formed over a peripheral region, thereby enabling improved processability and productivity.

Reference will now be made in detail to the embodiments of the disclosed technology, examples of which are illustrated in the accompanying drawings. Wherever possible, the same reference numbers will be used throughout the drawings to refer to the same or like parts. While the disclosed technology is susceptible to various modifications and alternative forms, specific embodiments thereof are shown by way of example in the drawings. However, the disclosed technology should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

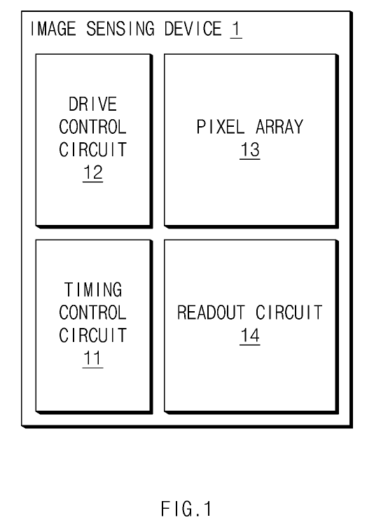

FIG. 1 is a schematic diagram illustrating an example of an image sensing device 1 based on some embodiments of the disclosed technology.

Referring to FIG. 1, the image sensing device 1 according to an example embodiment of the disclosed technology may include a timing control circuit 11, a drive control circuit 12, a pixel array 13, and a readout circuit 14. The constituent components of the image sensing device 1 illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The timing control circuit 11 may provide a timing signal and a control signal to at least one of the drive control circuit 12 and the readout circuit 14. The drive control circuit 12 may activate the pixel array 13 to perform specific operations on pixels included in a corresponding row based on the timing signal and the control signals provided from the timing control circuit 11.

The drive control circuit 12 may generate a row selection signal to select at least one row among the plurality of rows. Pixels of the row selected by the drive control circuit 12 may sequentially transmit a reference signal and an image signal to the readout circuit 14. Here, the reference signal and the image signal are analog signals. The reference signal may be an electrical signal that is provided to the readout circuit 14 when a floating diffusion region is reset, and the image signal may be an electrical signal that is provided to the readout circuit 14 when photocharges generated by the imaging pixel are accumulated in the floating diffusion region.

The pixel array 13 may include a plurality of pixels (PXs) arranged in rows and columns. The plurality of pixels may be connected to the row driver through a plurality of row lines extending in a row direction.

Each of the plurality of pixels included in the pixel array 13 may output a pixel signal in response to incident light received from the outside. Each of the plurality of pixels may be arranged in a two-dimensional (2D) structure. For example, each of the plurality of pixels may be arranged in a matrix structure. The plurality of pixels may be arranged in a first direction and a second direction. For example, the plurality of pixels may be arranged in a row direction and a column direction.

Among light incident upon the pixel, light of a specific wavelength band (e.g., red light, green light, or blue light) may pass through an optical filter arranged in an active pixel, and light having penetrated the optical filter may be focused onto at least one photoelectric conversion element. The photoelectric conversion element may generate photocharges in response to incident light. An electric signal may be generated by the pixel in response to the amount of generated photocharges.

When the pixel operates in a state where the amount of incident light is very small or there is no incident light (hereinafter referred to as a dark condition), the pixel may generate a dark signal. Signals generated under dark conditions may be signals corresponding to a noise component generated inside the image sensing device 1.

The readout circuit 14 may sample the electrical signals output from the pixel array 13, may convert the sampled electrical signals into digital signals, and may output the digital signals to an image signal processor. For example, the readout circuit 14 may include a correlated double sampler (CDS), an analog-to-digital converter (ADC), an output buffer, a column driver, etc.

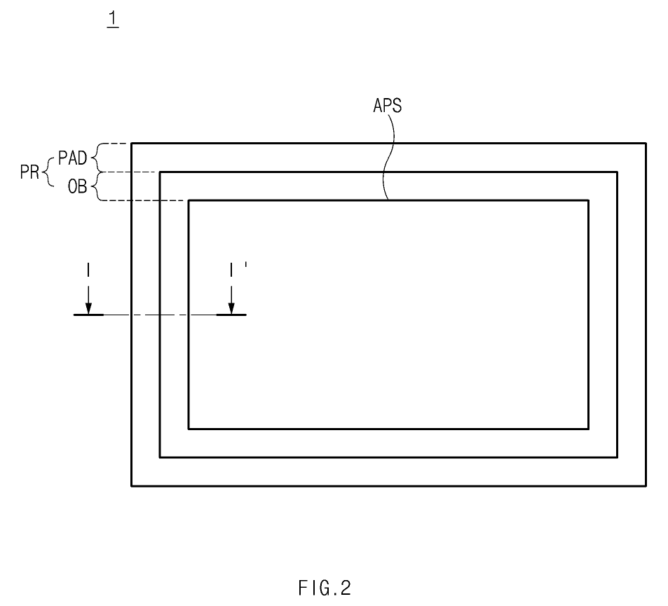

FIG. 2 is a plan view illustrating a portion of the image sensing device 1 shown in FIG. 1 based on some embodiments of the disclosed technology.

Referring to FIG. 2, the image sensing device 1 may include an active pixel region (APS) and a peripheral region (PR).

The active pixel region (APS) may be a region including active pixels that are arranged in a two-dimensional (2D) matrix configuration within the pixel array 13 shown in FIG. 1. Each of the active pixels may include at least one photoelectric conversion element. Each of the active pixels may generate charges from incident light using the photoelectric conversion element, and may process the charges to output an electric signal. Each of the active pixels may include at least one transistor among a transfer transistor, a reset transistor, an amplification transistor, or a selection transistor.

The peripheral region (PR) may be arranged adjacent to at least one side of the active pixel region (APS). For example, the peripheral region (PR) may be arranged to surround the active pixel region (APS). The peripheral region (PR) may include a light blocking region (OB) arranged outside the active pixel region (APS), and a pad region (PAD) arranged outside the light blocking region (OB). The light blocking region (OB) may be disposed between the active pixel region (APS) and the pad region (PAD). In an example embodiment, the pad region (PAD) may surround all side surfaces of the light blocking region (OB). In another embodiment, the pad region (PAD) may not surround some portions of side surfaces of the light blocking region (OB).

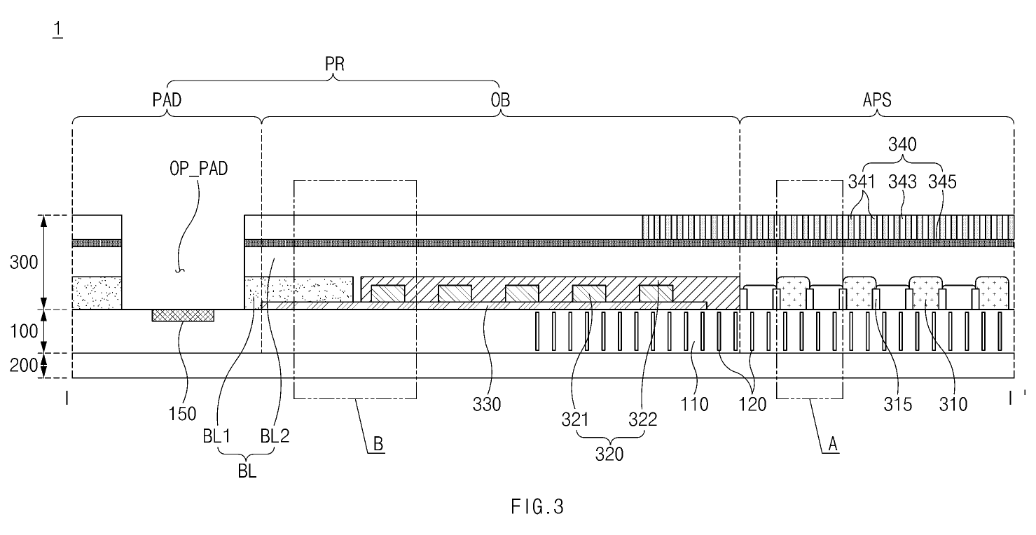

The light blocking region (OB) may be a region that prevents or impedes incident light from passing through a semiconductor layer 100 (see FIG. 3). The light blocking region (OB) may include photosensing pixels known as “black pixels” at where the incident light is blocked by light blocking region (OB) so that the electrical signals output by the black pixels in the light block region (OB) are generated without receiving incident light and thus are electrical signals that represent a level of photocharge or a current generated without the incident light. Accordingly, the electrical signals from the black pixels can be used to correct the black level or dark level of the active pixels. For example, the black pixels may be pixels configured to output the dark signal of FIG. 1.

The pad region (PAD) may be a region including an input/output (I/O) pad 150 (see FIG. 3) for signal communication with an external device of the image sensing device 1. In some implementations, the I/O pad refers to a pad configured to transmit and receive electrical signals. The internal circuit of the image sensing device 1 may be electrically connected to the external device through the pad region (PAD).

FIG. 3 is a cross-sectional view illustrating an example of the image sensing device taken along the line I-I’ shown in FIG. 2 based on some embodiments of the disclosed technology.

In FIG. 3, the size ratio between adjacent nanostructures and components may be exaggerated for ease of illustration and may be different from the actual size ratio.

Referring to FIG. 3, the image sensing device 1 may include a semiconductor layer 100, an interconnect layer 200, and a light reception layer 300.

The semiconductor layer 100 may include a first surface configured to receive incident light and a second surface facing away from or opposite to the first surface. The light reception layer 300 may face the first surface, and the interconnect layer 200 may face the second surface. The semiconductor layer 100 may be a layer configured to generate charges by converting the incident light.

The semiconductor layer 100 may include a semiconductor substrate 110 and a pixel isolation portion 120.

The semiconductor substrate 110 may include silicon, germanium, silicon-germanium, a group II-VI compound semiconductor, or a group III-V compound semiconductor. The semiconductor substrate 110 may include impurities of a first conductivity type.

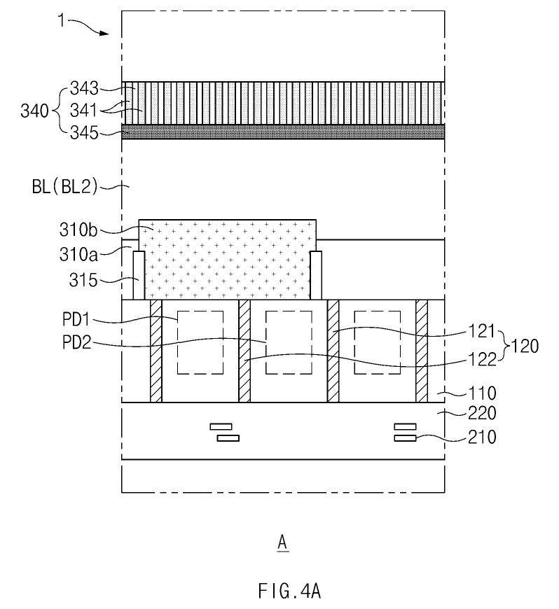

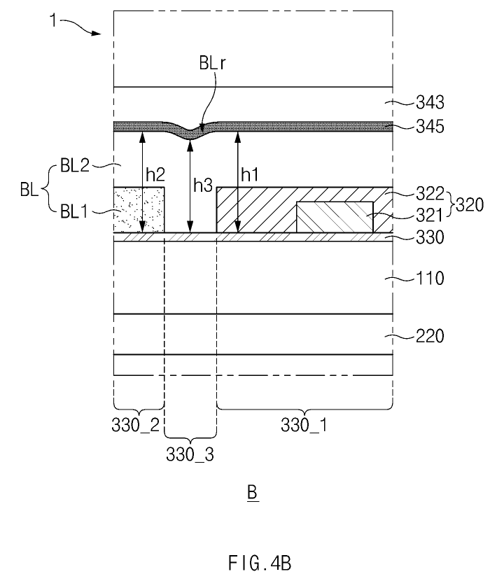

The semiconductor substrate 110 may include photoelectric conversion regions (PD1, PD2) (see FIG. 4A) that generate charges from the incident light. Each of the photoelectric conversion regions (PD1, PD2) may be a region including the photoelectric conversion element of FIGS. 1 and 2. The photoelectric conversion element may include at least one of a photodiode, a phototransistor, a photogate, or a pinned photodiode. In an example embodiment, each of the photoelectric conversion regions (PD1, PD2) may be a region including impurities of a second conductivity type different from the first conductivity type within the semiconductor substrate 110. For example, the first conductivity type may be P-type, and the second conductivity type may be N-type.

The pixel isolation portion 120 may be disposed in a trench that penetrates into the semiconductor substrate 110 by a predetermined depth. For example, the pixel isolation portion 120 may be formed as a deep trench isolation (DTI) structure. The pixel isolation portion 120 may electrically isolate a plurality of active pixels from each other. The pixel isolation portion 120 may include an insulation material such as silicon oxide, silicon nitride, or a high-permittivity (high-k) material. However, in some example embodiments, the pixel isolation portion 120 may include a liner layer including the insulation material, and a conductive material layer such as polycrystalline silicon.

In an example embodiment, the interconnect layer 200, the semiconductor layer 100, and the light reception layer 300 may be sequentially stacked. In this case, in each of the active pixel region (APS), the light blocking region (OB), and the pad region (PAD) of FIG. 2, the semiconductor layer 100 may be disposed over the interconnect layer 200 and may be disposed under the light reception layer 300.

In the semiconductor layer 100, each of the photoelectric conversion regions (PD1, PD2) (see FIG. 4A) of the semiconductor substrate 110 may be disposed in the active pixel region (APS) and the light blocking region (OB). The photoelectric conversion region (PD1, PD2) may function as a photoelectric conversion element of the active pixel within the active pixel region (APS), and may function as a photoelectric conversion element of the black pixel within the light blocking region (OB). In an example embodiment, some of the photoelectric conversion regions within the light blocking region (OB) may be a dummy region of a dummy pixel. In some implementations, the term “dummy pixel” refers to a pixel that is structured like an active pixel but is not used for detecting the incident light for actual image capture, and is used to serve other purposes such as ensuring process uniformity, enhancing circuit stability, and operating as a dark pixel for providing a reference for black level calibration.

The pixel isolation portion 120 may be disposed in the active pixel region (APS). In addition, the pixel isolation portion 120 may also be disposed in some parts (e.g., a region where the black pixels are arranged) of the light blocking region (OB).

The semiconductor layer 100 may further include an input/output (I/O) pad 150 having a portion exposed to the outside in the pad region (PAD). For example, the input/output (I/O) pad 150 may be configured such that a top surface of the input/output (I/O) pad 150 is exposed to the outside by a pad opening (OP_PAD) formed to penetrate a base layer (BL). The input/output (I/O) pad 150 may be electrically connected to a circuit of the semiconductor layer 100 or the interconnect layer 200. Although the input/output (I/O) pad 150 is illustrated as being embedded in the semiconductor substrate 110 for convenience of description, the disclosed technology is not limited thereto, and it should be noted that the input/output (I/O) pad 150 may be implemented in various forms as long as at least a portion of the input/output (I/O) pad 150 is exposed to the outside. For example, the input/output (I/O) pad 150 may be arranged on the top surface of the semiconductor substrate 110.

The interconnect layer 200 may include elements and interconnect lines configured to carry or process electrical signals generated by the photoelectric conversion element and carry control signals to be used to control the active pixels. The interconnect layer 200 may include a plurality of interconnect lines 210 (see FIG. 4A) including at least one layer, and an interlayer insulation layer 220 (see FIG. 4A) covering the interconnect lines 210.

The interconnect layer 200 may include a gate structure that is in contact with a bottom surface of the semiconductor substrate 110. The gate structure may form at least one of a transfer transistor, a reset transistor, an amplification transistor, or a selection transistor described in FIG. 1 together with some regions (e.g., a source/drain region) of the semiconductor substrate 110.

The interconnect layer 200 may cover one surface of the semiconductor layer 100 under the semiconductor layer 100. The interconnect lines 210 (see FIG. 4A) of the interconnect layer 200 may be disposed in at least one of the active pixel region (APS), the light blocking region (OB), and the pad region (PAD).

The light reception layer 300 may include a color filter layer 310, a grid 315, a light scattering suppression layer 320, a light blocking layer 330, a base layer (BL), and a lens layer 340.

The color filter layer 310 may include color filters respectively corresponding to the photoelectric conversion regions (PD1, PD2) of the semiconductor substrate 110. The color filter may include a green color filter that transmits green light while blocking light in other colors, a red color filter that transmits red light while blocking light in other colors, and a blue color filter that transmits blue light while blocking light in other colors. The color filter may selectively transmit specific wavelengths of incident light to determine the type of light received by the photoelectric conversion regions (PD1, PD2) or the type of active pixel. The color filter layer 310 may be a layer in which a plurality of color filters is arranged in a two-dimensional pattern (e.g., a Bayer pattern). The color filter layer 310 may be arranged on the semiconductor layer 100 in the active pixel region (APS) for capturing color information of the images carried in the incident light.

The grid 315 may be disposed between the plurality of color filters, and may prevent reflection of light or may guide light so that incident light can smoothly reach the photoelectric conversion regions (PD1, PD2). A bottom surface of the grid 315 may be located at substantially the same height as the bottom surfaces of the color filters. The grid 315 has a lower height than the color filters, and the color filter layer 310 may cover the grid 315. The grid 315 can include a conductive material. The grid 315 may be disposed over the semiconductor layer 100 in the active pixel region (APS).

The light scattering suppression layer 320 may reduce or suppress the scattering of light and may be arranged to be spaced apart from the color filter layer 310. The light-scattering suppression layer 320 may be disposed on the semiconductor layer 100 in the light blocking region (OB). The light-scattering suppression layer 320 may prevent light (e.g., light that is not directly incident upon the semiconductor layer 100 in the light blocking region (OB) but is instead reflected from the semiconductor layer 100) from being scattered into the photoelectric conversion regions (PD1, PD2) of the active pixel region (APS). In some implementations, the light-scattering suppression layer 320 may include the same material as the color filters of the color filter layer 310. At least a portion of the light-scattering suppression layer 320 may be formed through the same process as the color filter layer 310.

In an example embodiment, the light-scattering suppression layer 320 may include a plurality of patterns 321 and a cover layer 322 covering the plurality of patterns 321. The plurality of patterns 321 may filter light of a different wavelength from the cover layer 322. For example, the cover layer 322 may include the same material as the blue color filter, and the plurality of patterns 321 may include the same material as the green color filter. In this case, the plurality of patterns 321 may be formed through the same process as the green color filter of the color filter layer 310. However, the configuration and shape of the light-scattering suppression layer 320 are not limited thereto, and may also be modified in various ways.

The light blocking layer 330 may be disposed on the semiconductor layer 100 in the light blocking region (OB). The light blocking layer 330 may include a portion disposed between the semiconductor layer 100 and the light-scattering suppression layer 320. The light-scattering suppression layer 320 may cover at least a portion of the top surface of the light blocking layer 330. The light blocking layer 330 may prevent light from being incident upon the semiconductor layer 100. The light blocking layer 330 may include a material that reflects or absorbs incident light. For example, the light blocking layer may include a material such as chromium (Cr), copper (Cu), tungsten (W), manganese dioxide (MnO2), or graphite.

The base layer (BL) may cover at least a portion of the color filter layer 310, the light-scattering suppression layer 320, and the light blocking layer 330. The base layer (BL) may be disposed in the active pixel region (APS), the light blocking region (OB), and the pad region (PAD). The base layer (BL) may provide a flat upper surface for forming the lens layer 340. The base layer (BL) may include a transparent material. The base layer (BL) may include a thermosetting material or a photocurable material, for example, an epoxy resin, a polyurethane resin, a polyester resin, an acrylic resin, a silicone resin, etc.

The base layer (BL) may include a first base layer BL1 and a second base layer BL2 covering at least a portion of the first base layer BL1. The first base layer BL1 may be disposed on at least one of the light blocking region (OB) and the pad region (PAD) that are used as peripheral regions (PRs). The second base layer BL2 may be disposed on the peripheral region (PR) and the active pixel region (APS). The first base layer BL1 may include a different material from the second base layer BL2. However, in some embodiments, the first base layer BL1 may include the same material as the second base layer BL2, and even if the first and second base layers (BL1, BL2) include the same material, a boundary between the first base layer BL1 and the second base layer BL2 may still be distinguishable depending on process conditions. The first base layer BL1 may be spaced apart from the light-scattering suppression layer 320.

The lens layer 340 may include a support layer 345, a plurality of nanostructures 341, and a dielectric layer 343 on the base layer (BL).

The support layer 345 may be a liner layer that conformally covers a top surface of the base layer (BL). The support layer 345 may include an insulation material such as silicon oxide or a low-temperature oxide (LTO).

The plurality of nanostructures 341 may be arranged on the support layer 345 with spacing between adjacent nanostructures. The plurality of nanostructures 341 may be in contact with the top surface of the support layer 345. The plurality of nanostructures 341 may be arranged to cause the phase of the incident light to vary depending on its position. Each of the plurality of nanostructures 341 may have a size smaller than the wavelength of visible light or the blue wavelength, for example, a width or height ranging from several nanometers (nm) to several hundred nanometers. The plurality of nanostructures 341 may include a dielectric material having a higher refractive index than air. For example, the plurality of nanostructures 341 may include a metal oxide such as titanium dioxide, gallium nitride, silicon nitride, or silicon.

The dielectric layer 343 may be arranged between the plurality of nanostructures 341 on the support layer 345. The dielectric layer 343 may include a material having a lower refractive index than the plurality of nanostructures 341, such as silicon oxide, silicon nitride, aluminum oxide, etc. However, in some embodiments, the lens layer 340 may omit a structure of a separate dielectric layer 343 and may use air as the dielectric material.

By using a nanostructure that provides a meta-surface instead of a curved lens structure with substantial thickness for aberration compensation, the image sensing device 1 having a relatively small thickness can be provided. The shape and arrangement pattern of the plurality of nanostructures 341 may be modified in various ways depending on the optical function to be implemented by the metalens.

FIG. 4A is an enlarged cross-sectional view illustrating an example of the region (A) shown in FIG. 3 based on some embodiments of the disclosed technology.

Referring to FIG. 4A, the photoelectric conversion regions (PD1, PD2) are classified into a first photoelectric conversion region (PD1) and a second photoelectric conversion region (PD2) that are arranged to be spaced apart from each other. The first photoelectric conversion region (PD1) and the second photoelectric conversion region (PD2) may form one unit pixel. In this case, the pixel isolation portion 120 may include a main pixel isolation portion 121, which separates the unit pixels from each other, and an auxiliary pixel isolation portion 122 disposed between the first photoelectric conversion region (PD1) and the second photoelectric conversion region (PD2). The main pixel isolation portion 121 may be formed in a trench having a depth that is equal to or greater than that of the auxiliary pixel isolation portion 122.

The color filter layer 310 may include a first color filter 310a and a second color filter 310b. The first color filter 310a and the second color filter 310b may be different types of color filters. As illustrated in FIG. 3, the color filter layer 310 may have a green color filter, a red color filter, and a blue color filter that are arranged in a Bayer pattern, and each of the first color filter 310a and the second color filter 310b may be one of the green color filter, the red color filter, and the blue color filter. For example, the first color filter 310a may be a green color filter, and the second color filter 310b may be a red color filter. The first color filter 310a may have a smaller height than the second color filter 310b, but may have substantially the same height based on some embodiments. Each of the first color filter 310a and the second color filter 310b may correspond to one of the unit pixels. For example, the first color filter 310a may filter the wavelength of light received by the first photoelectric conversion region (PD1) and the second photoelectric conversion region (PD2), and may allow light of specific wavelengths to pass therethrough.

The grid 315 may include a bottom surface having the same level as the bottom surface of the color filter layer 310. For example, the bottom surface of the grid 315 may be coplanar with the bottom surface of the color filter layer 310. The grid 315 may be arranged to correspond to the main pixel isolation portion 121. In FIG. 4A, the grid 315 is illustrated as being arranged to be partially vertically misaligned with the main pixel isolation portion 121, but is not limited thereto. It should be noted that the grid 315 may also be modified in various ways depending on a distance from the center of the active pixel region APS (see FIG. 2) or a design change of the image sensing device.

Although FIG. 4A illustrates the semiconductor layer 100 (see FIG. 3) and the light reception layer 300 (see FIG. 3) based on a 2PD (two-PD) structure, the disclosed technology is not limited thereto, and it should be noted that the number of photoelectric conversion regions corresponding to the unit pixels may be changed to 1 or 4, etc.

Among the base layers (BL), the second base layer BL2 may cover at least a portion of the top surface of the color filter layer 310 in the active pixel region (APS) (see FIG. 3). The second base layer BL2 may provide a flat surface for forming the lens layer 340 of the active pixel region (APS). Since the support layer 345 is formed within a uniform thickness on the second base layer BL2 and the nanostructures 341 are formed on the second base layer BL2 having a flat upper surface, the plurality of nanostructures 341 may have substantially the same height. Accordingly, a highly reliable metalens may be implemented.

In the active pixel region (APS), the thickness of the second base layer BL2 may be larger than an average thickness of the color filter layer 310.

FIG. 4B is an enlarged cross-sectional view illustrating an example of the region (B) shown in FIG. 3 based on some embodiments of the disclosed technology.

Referring to FIG. 4B, a first base layer BL1 among the base layers (BL) may be disposed in the peripheral region PR (see FIG. 2) and not disposed in the active pixel region APS (see FIG. 2). The first base layer BL1 may include a top surface having substantially the same height as the top surface of the light-scattering suppression layer 320. However, depending on process conditions, the height of the top surface of the first base layer BL1 may be different from the height of the top surface of the light-scattering suppression layer 320 by a certain length, or may be formed at a higher level than the top surface of the light-scattering suppression layer 320. The first base layer BL1 may be a layer for minimizing a step difference caused by the color filter layer 310 or the light-scattering suppression layer 320 of FIG. 3. In some implementations, the first base layer BL1 may be disposed to prevent some components from remaining in the peripheral region (PR) in a subsequent process (e.g., a planarization process) for forming the lens layer 340, thereby enabling the fabrication of the image sensing device 1 with improved productivity. For example, when the deposition and planarization process is performed to form the plurality of nanostructures 341 (see FIG. 4A), the first base layer BL1 may compensate for thickness differences between the color filter layer 310 (see FIG. 4A) or the light-scattering suppression layer 320. Accordingly, the height of the top surface of the second base layer BL2 may be adjusted to be the same or similar in both the active pixel region (APS) and the light blocking region (OB), thereby preventing the conductive material used for the plurality of nanostructures 341 from remaining in the planarization process.

The light blocking layer 330 may be formed within a uniform thickness on the semiconductor substrate 110. The light blocking layer 330 may include a first portion 330_1 disposed between the semiconductor substrate 110 of the semiconductor layer 100 (see FIG. 3) and the light-scattering suppression layer 320, a second portion 330_2 disposed between the semiconductor substrate 110 and the first base layer BL1, and a third portion 330_3 disposed between the first portion 330_1 and the second portion 330_2. The first to third portions (330_1, 330_2, 330_3) may have a uniform thickness, and may be integrally connected to each other.

The first base layer BL1 may be arranged on the light blocking layer 330 and spaced apart from the light-scattering suppression layer 320. The first base layer BL1 may be spaced apart from the light-scattering suppression layer 320 in a first direction parallel to the top surface of the semiconductor substrate 110 in consideration of a process margin. The light-scattering suppression layer 320 may be arranged on the first portion 330_1 of the light blocking layer 330, and the first base layer BL1 may be arranged on the second portion 330_2 of the light blocking layer 330.

The second base layer BL2 may include a portion disposed in the active pixel region APS (see FIGS. 3 and 4A) and a portion disposed in the peripheral region PR (see FIG. 3). In the peripheral region (PR), the second base layer BL2 may cover at least a portion of the light-scattering suppression layer 320 and the first base layer BL1. The second base layer BL2 may include a portion that extends between the light-scattering suppression layer 320 and the first base layer BL1 while covering the top surfaces of the light-scattering suppression layer 320 and the first base layer BL1. For example, the second base layer BL2 may extend between the light-scattering suppression layer 320 and the first base layer BL1, and may contact the third portion 330_3 of the light blocking layer 330.

The second base layer BL2 may include a first top surface having a first height (h1) from the top surface of the light blocking layer 330 either in a region vertically overlapping the light-scattering suppression layer 320 or in a region located above the first portion 330_1. The second base layer BL2 may include a second top surface having a second height (h2) from the top surface of the light blocking layer 330 either in a region vertically overlapping the first base layer BL1 or in a region located above the second portion 330_2. The second base layer BL2 may include a third top surface having a third height (h3) from the top surface of the light blocking layer 330 in a region disposed between the first base layer BL1 and the light-scattering suppression layer 320 or in a region located above the third portion 330_3. The third height (h3) may be less than the first height (h1), and the third height (h3) may be less than the second height (h2).

The second base layer BL2 may include a groove portion (BLr) recessed toward the top surface of the semiconductor substrate 110 on the third portion 330_3. The top surface of the groove portion (BLr) may have a third height (h3) that is less than those of adjacent regions. The groove portion (BLr) may be a portion formed by filling not only a relatively larger space than the adjacent region, but also the region between the first base layer BL1 and the light-scattering suppression layer 320, during the process of forming the second base layer BL2. The groove portion (BLr) may be located outside the end of the light-scattering suppression layer 320. In some embodiments, the groove portion (BLr) may have a line shape that extends along the outer surface of the end of the light-scattering suppression layer 320 on a plane. In this case, the groove portion (BLr) may have a line shape extending in a second direction perpendicular to the first direction in which the light-scattering suppression layer 320 and the first base layer BL1 are spaced apart from each other. The groove portion (BLr) may be located in the light blocking region OB (see FIG. 4A).

Hereinafter, the image sensing devices based on some embodiments of the disclosed technology will be described with reference to the attached drawings. The following embodiment will hereinafter be described with a focus on the lens layer and the base layer for convenience of description, but other implementations are also possible, and it should be understood that the disclosed technology also includes a combination of such embodiments as necessary.

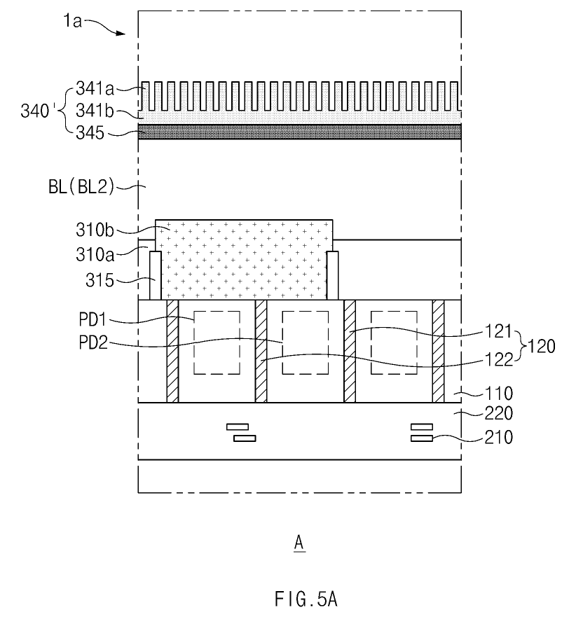

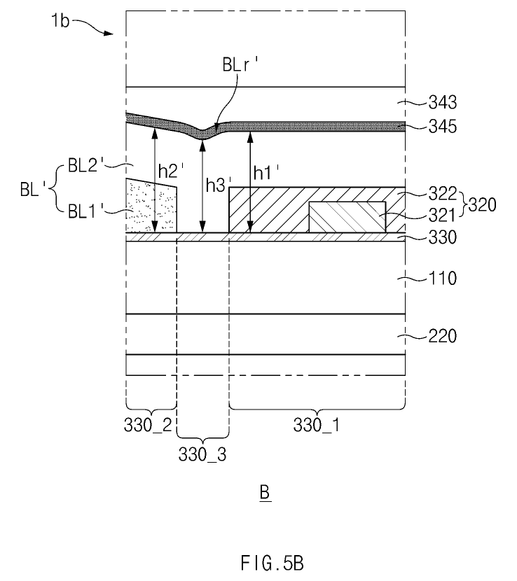

FIG. 5A is an enlarged cross-sectional view illustrating another example of the region (A) shown in FIG. 3 based on some embodiments of the disclosed technology.

FIG. 5A illustrates a region corresponding to the ‘A’ region of FIG. 4A within the image sensing device (1a) according to an example embodiment.

Referring to FIG. 5A, the image sensing device (1a) may have a lens layer 340’ different from the image sensing device 1 of FIG. 4A. The lens layer 340’ may further include a support layer 345, a plurality of nanostructures 341a on the support layer 345, and a conductive liner layer 341b disposed between the support layer 345 and the plurality of nanostructures 341a. The conductive liner layer 341b may be a liner layer having a uniform thickness on the support layer 345.

The conductive liner layer 341b may include the same material (e.g., titanium oxide) as the plurality of nanostructures 341a. The conductive liner layer 341b may be integrally connected to a plurality of nanostructures 341a. The conductive liner layer 341b may be connected to the bottom surface of each of the plurality of nanostructures 341a.

As illustrated in FIGS. 3-4B, as the base layer (BL) is formed divisionally in two stages, a base layer (BL) without a step difference in the peripheral region PR (see FIG. 3) and the active pixel region (APS) can be provided. Accordingly, productivity of the image sensing device (1a) can be improved even when the lens layer 340’ includes the conductive liner layer 341b.

In some embodiments, the lens layer 340’ may use air as a dielectric layer without including a separate material layer between the plurality of nanostructures 341a. In this case, even if the spacing between the plurality of nanostructures 341a is not filled with a separate material layer, the conductive liner layer 341b is integrally connected to the plurality of nanostructures 341a while being disposed under the plurality of nanostructures 341a, enabling the conductive liner layer 341b to serve as a support structure that prevents the plurality of nanostructures 341a from being broken or damaged. However, in some embodiments, the lens layer 340’ may include a separate dielectric layer between the plurality of nanostructures 341a.

FIG. 5B is an enlarged cross-sectional view illustrating an example of the region (B) shown in FIG. 3 based on some embodiments of the disclosed technology.

Specifically, FIG. 5B illustrates a region corresponding to the ‘B’ region of FIG. 4B within the image sensing device (1b) depending on an example embodiment.

Referring to FIG. 5B, in the first base layer (BL1’) of the image sensing device (1b), a vertical thickness of an end portion of the first base layer (BL1’) facing the light-scattering suppression layer 320 may be smaller than a thickness of the remaining region other than the end portion. For example, the thickness of the first base layer (BL1’) may gradually increase in the vertical direction as it extends away from the light-scattering suppression layer 320. This variation in thickness results from a step difference between a region where the light blocking layer 330 is formed and another region where the light blocking layer 330 is not formed, during the material deposition process for forming the first base layer (BL1’).

Each of the second base layer (BL2’) and the support layer 345 may be formed to correspond to the shape of the top surface of the first base layer (BL1’), and may have a top surface that increases in height with increase in distance from the light-scattering suppression layer 320.

The second base layer (BL2’) includes a top surface having a first height (h1’) measured from the top surface of the light blocking layer 330 in a region vertically overlapping the light-scattering suppression layer 320 or in a region located above the first portion 330_1. The second base layer (BL2') may include a top surface having a second height (h2’) measured from the top surface of the light blocking layer 330 in a region vertically overlapping the first base layer (BL1’) or in a region located above the second portion 330_2. The second height (h2’) may correspond to the highest height or an average height among those of the regions located above the first base layer (BL1’). The second base layer (BL2’) includes a top surface having a third height (h3') measured from the top surface of the light blocking layer 330 in a region between the first base layer (BL1’) and the light-scattering suppression layer 320 or in a region located above the third portion 330_3. The third height (h3’) may be less than the first height (h1’), and the third height (h3’) may be less than the second height (h2’). The second height (h2’) may be greater than the first height (h1’).

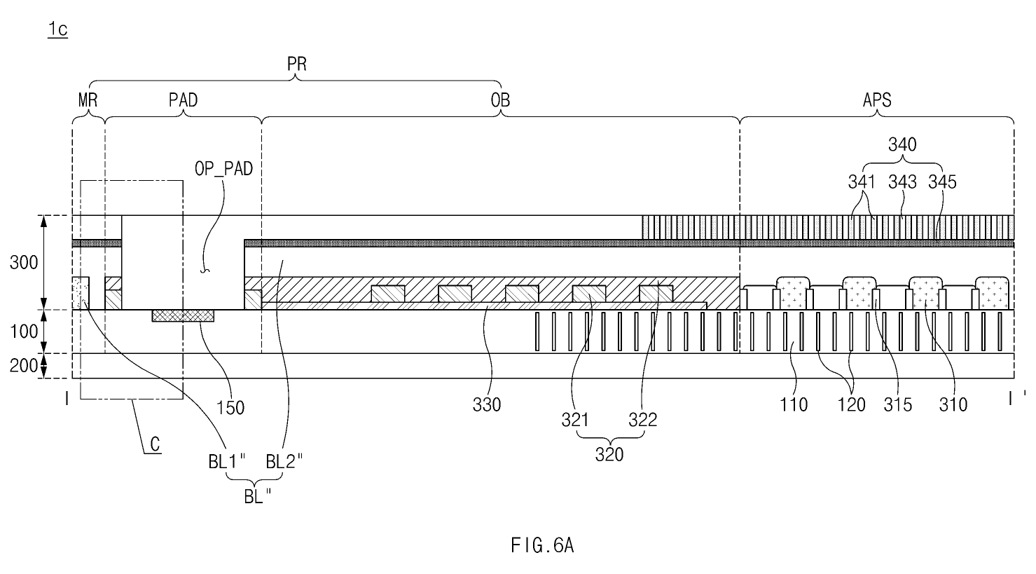

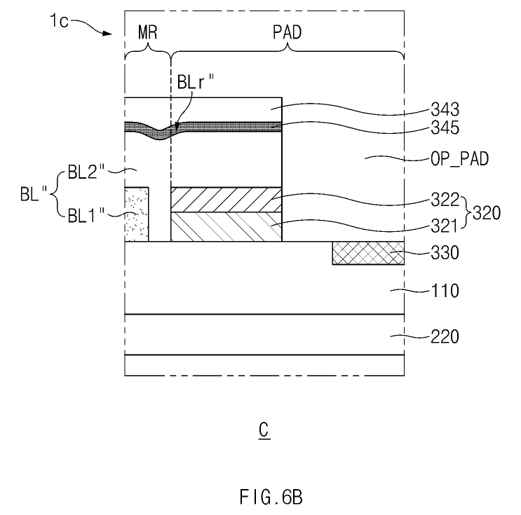

FIG. 6A is a cross-sectional view illustrating another example of the image sensing device taken along the line I-I’ shown in FIG. 2 based on some embodiments of the disclosed technology. FIG. 6A illustrates a cross-sectional view corresponding to the cross-sectional view of FIG. 3 in the image sensing device (1c) based on an example embodiment. FIG. 6B is an enlarged cross-sectional view illustrating an example of the region (C) shown in FIG. 6A based on some embodiments of the disclosed technology.

Referring to FIG. 6A, the peripheral region (PR) of the image sensing device (1c) may include a light blocking region (OB), a pad region (PAD), and a margin region (MR).

The margin region (MR) may be located outside the pad region (PAD). The margin region (MR) may be a region that takes into account the process margin in the process of dicing the semiconductor layer 100 or the semiconductor substrate 110 along a scribe line (S/L) region.

The light-scattering suppression layer 320 may include a portion extending from the light blocking region (OB) to the pad region (PAD). The light-scattering suppression layer 320 may include a portion that extends to a region outside the input/output (I/O) pad 150 and passes through the pad opening (OP_PAD). In some embodiments, the margin region (MR) may refer to the entire peripheral region (PR) located outside the light-scattering suppression layer 320.

Referring to FIG. 6B, a groove portion (BLr”) of the image sensing device (1c) may be disposed in the margin region (MR). As the light-scattering suppression layer 320 extends to the pad region (PAD), the groove portion (BLr”) may be located outside the light-scattering suppression layer 320. The region excluding the groove portion (BLr”) of the margin region (MR) may be provided with a flat upper surface by the first and second base layers (BL1, BL2). In this case, unlike as described in FIG. 4B, the groove portion may not be arranged in the light blocking region (OB). The image sensing device based on some embodiments of the disclosed technology may be configured such that a plurality of nanostructures 341 (see FIG. 4A) is formed on the base layer (BL) and process defects (e.g., defects in the dicing process) caused by the remaining material layer are alleviated, enabling the image sensing device with improved processability.

In plan view, the groove portion (BLr”) may be shaped to extend along the outer surface of the light-scattering suppression layer 320 in the margin region (MR).

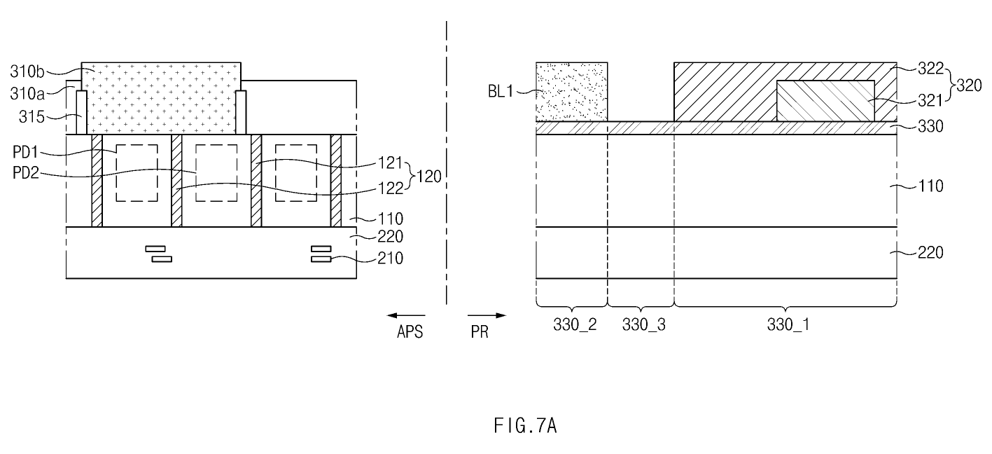

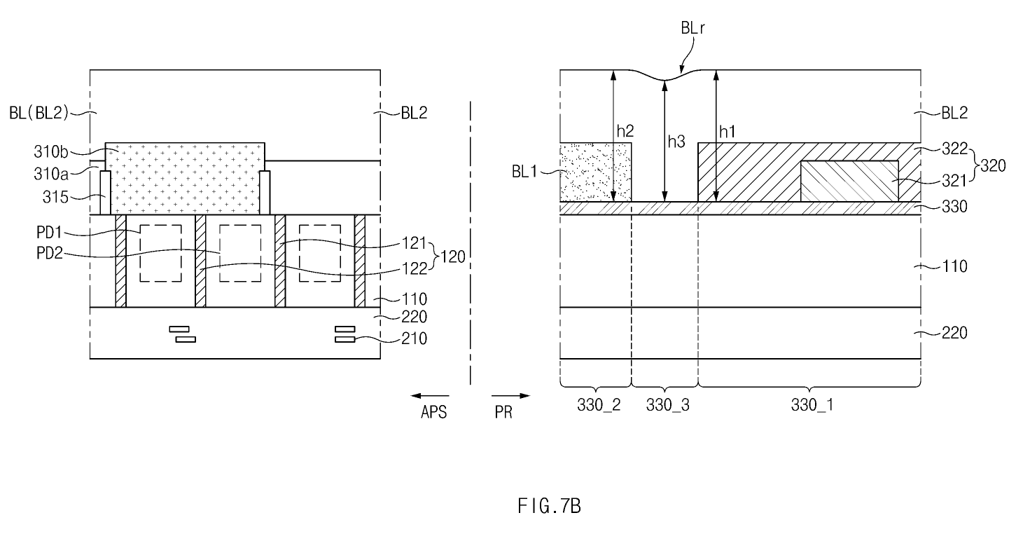

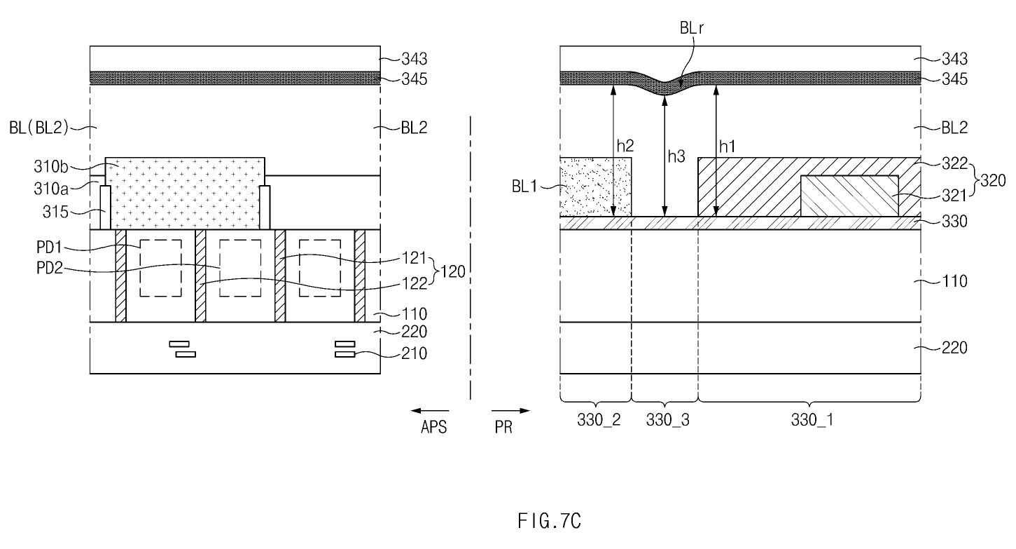

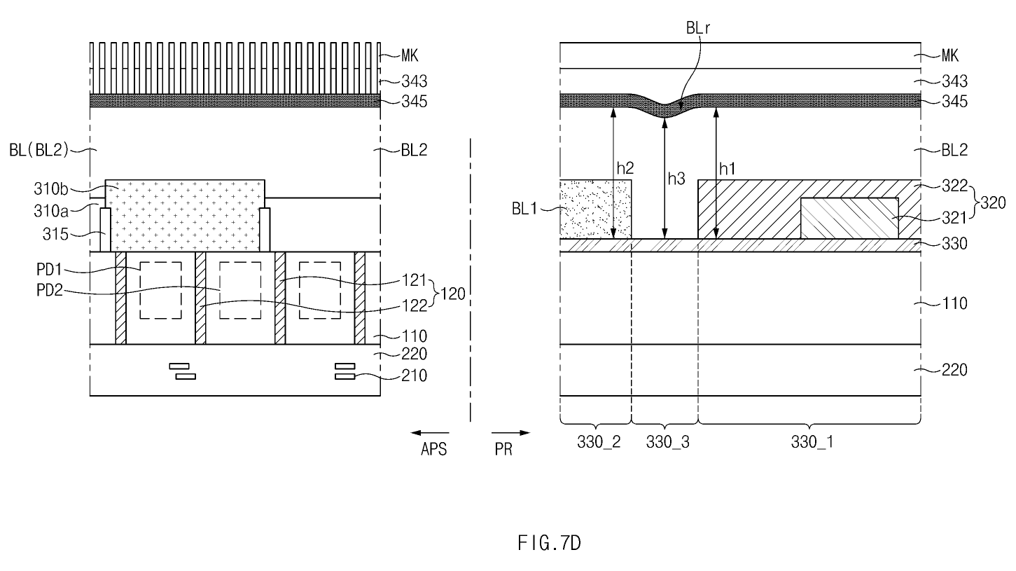

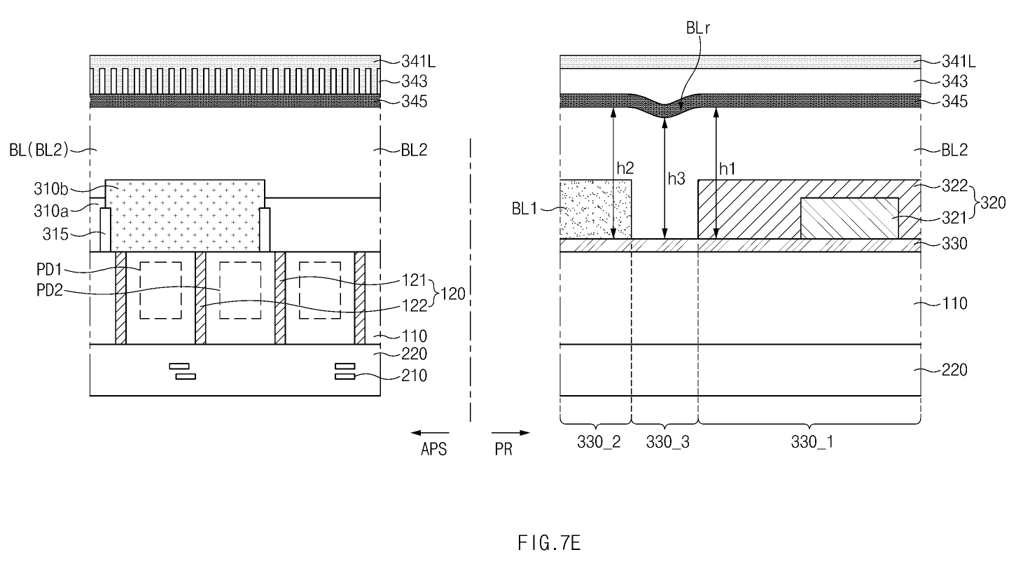

FIGS. 7A-7E are cross-sectional views illustrating examples of a method for manufacturing the image sensing device based on some embodiments of the disclosed technology.

FIGS. 7A-7E illustrates example methods for manufacturing the image sensing device including the active pixel region (APS) and the peripheral region (PR) that are used as regions respectively corresponding to the structures of FIGS. 4A and 4B.

Referring to FIG. 7A, the color filter layers (310a, 310b), the light-scattering suppression layer 320, and the first base layer BL1 may be formed on the semiconductor substrate 110.

First and second photoelectric conversion regions (PD1, PD2) may be formed in the semiconductor substrate 110, and an insulation material may be deposited in a trench formed by etching at least a portion of the semiconductor substrate 110 to form a pixel isolation portion 120. Thereafter, the interconnect layers (210, 220) may be formed on the back surface of the semiconductor substrate 110.

Subsequently, in the active pixel region (APS), a conductive material layer may be deposited on the top surface of the semiconductor substrate 110 and a patterning process may be performed to form the grid 315. The color filter layers (301a, 310b) may be formed on the semiconductor substrate 110 to have a thickness greater than that of the grid 315. In some embodiments, when depositing some of the color filter materials of the color filter layers (310a, 310b), patterns 321 may be deposited together in the peripheral region (PR). A light blocking layer 330 may be deposited on the semiconductor substrate 110 to a certain thickness before forming the patterns 321 in the peripheral region (PR). Thereafter, a cover layer 322 may be formed by depositing a material identical or similar to a material of blue color to cover the patterns 321 and the light blocking layer 330, thereby forming the light-scattering suppression layer 320.

Subsequently, a thermosetting material or a photocurable material may be deposited in a region spaced apart from the light-scattering suppression layer 320 within the peripheral region (PR) using a mask, and an annealing process may then be performed, forming the first base layer BL1. Through the annealing process, the height of the material may be reduced, and the first base layer BL1 finally formed thereafter may be formed to have a top surface having substantially the same height as a top surface of the light-scattering suppression layer 320. However, since the height of the top surface of the first base layer BL1 and the height of the top surface of the light-scattering suppression layer 320 are formed through separate processes, an error range in the manufacturing process may occur in the range of 0.1% to 10%.

As the first base layer BL1 is formed, a difference in height between the first base layer BL1 and the color filter layers (310a, 310b) can be minimized even in a region where the light-scattering suppression layer 320 is not arranged. Accordingly, a processability in the subsequent process to be described later can be improved.

Referring to FIG. 7B, the second base layer BL2 may be formed.

A thermosetting material may be deposited on the active pixel region (APS) and the peripheral region (PR), so that the second base layer BL2 can be formed to cover the color filter layers (310a, 310b), the light-scattering suppression layer 320, and the first base layer BL1. The thermosetting material may be a different material from the material of the first base layer BL1, but may also be the same material as the first base layer BL1 depending on the embodiments. Even when the first base layer BL1 and the second base layer BL2 include the same material, a boundary between the first base layer BL1 and the deposited thermosetting material can be distinguished by the annealing process or the like. The annealing process may be performed or omitted after depositing the thermosetting material.

Since the second base layer BL2 includes a portion having a space between the first base layer BL1 and the light-scattering suppression layer 320, as described with reference to FIGS. 3-4B, the second base layer BL2 may have a third height (h3) that is lower than those of the remaining regions within the corresponding region as described with reference to FIGS. 3-4B.

Since the base layer BL is formed in two steps of forming the first base layer BL1 and the second base layer BL2, the second base layer BL2 may have a second height (h2) that is the same as or similar to the first height (h1) on the first base layer BL1, so that the base layer (BL) that provides a flat surface even in the peripheral region (PR) may be formed.

Referring to FIG. 7C, a support layer 345 and a dielectric layer 343 may be formed.

A low-temperature oxide (LTO) material may be deposited on the base layer (BL) to form the support layer 345, a dielectric material may be deposited on the support layer 345, and a planarization process may be performed to form the dielectric layer 343.

Referring to FIG. 7D, a plurality of penetration portions that penetrates a portion of the dielectric layer 343 may be formed by performing the etching process using a mask (MK). The mask (MK) may have a pattern on the active pixel region (APS). Since the dielectric layer 343 exposed to the outside by the mask (MK) may be etched according to the above pattern, a plurality of penetration portions by which the top surface of the support layer 345 is exposed outside may be formed.

Referring to FIG. 7E, a deposition process may be performed to fill the plurality of penetration portions, and a metamaterial layer 341L covering the top surface of the dielectric layer 343 may be formed. The metamaterial layer 341L may include metal oxide such as titanium dioxide, gallium nitride, silicon nitride, or silicon. The metamaterial layer 341L may have substantially the same top surface on the active pixel region (APS) and the peripheral region (PR) as the planar dielectric layer 343 is formed.

Thereafter, a planarization process may be performed to remove the metamaterial layer 341L on the dielectric layer 343, forming the plurality of nanostructures 341.

In some embodiments, unlike FIGS. 7D and 7E, the planarization process may be performed only after the metamaterial layer 341L is formed without performing the planarization process in the process of forming the dielectric layer 343, forming the plurality of nanostructures 341.

Since the base layer (BL) having the second height (h2) is provided in the peripheral region (PR), the metamaterial layer 341L may not remain on the peripheral region (PR) after the planarization process. For example, if the process of forming the first base layer BL1 is omitted, the top surface of the second base layer BL2 may be formed to have a low height in the peripheral region (PR), causing the metamaterial layer 341L to be located at a relatively low position. In this case, the metamaterial layer 341L may remain in the peripheral region (PR) during the planarization process, and a process defect may occur due to the presence of the remaining metamaterial layer 341L during a subsequent dicing process that is used for cutting semiconductor dies or forming an opening for exposing the input/output (I/O) pad 150 (see FIG. 3). Alternatively, to provide a flat surface, an excessive amount of base material may need to be deposited and subsequently planarized to form the base layer. In some example embodiments of the disclosed technology, the image sensing device may be configured to minimize the amount of the metamaterial layer 341L remaining on the peripheral region (PR). As a result, an image sensing device with improved productivity or processability can be achieved.

As is apparent from the above description, the embodiments of the disclosed technology provide an image sensing device in which a first base layer is formed over a peripheral region, enabling an image sensing device with improved processability or higher productivity.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
an active pixel region including a photoelectric conversion region configured to convert incident light into electrical signals; and
a peripheral region disposed adjacent to at least one side of the active pixel region, and including a light scattering suppression layer that reduces scattering of light, a first base layer spaced apart from the light scattering suppression layer, and a second base layer covering at least a portion of each of the light scattering suppression layer and the first base layer.

2. The image sensing device according to claim 1, wherein:
the second base layer extends to the active pixel region; and
the image sensing device further comprises a lens layer including a plurality of nanostructures spaced apart from each other on the second base layer of the active pixel region.

3. The image sensing device according to claim 2, wherein the lens layer further includes:
a dielectric layer disposed between the plurality of nanostructures.

4. The image sensing device according to claim 1, further comprising:
a semiconductor layer disposed below the light scattering suppression layer and the first base layer in the peripheral region, and including the photoelectric conversion region in the active pixel region; and
a light blocking layer disposed on at least a portion of the semiconductor layer, and including a first portion and a second portion,
wherein
the first portion is disposed below the light scattering suppression layer; and
the second portion is disposed below the first base layer.

5. The image sensing device according to claim 4, wherein the light blocking layer includes:
a third portion connecting the first portion to the second portion.

6. The image sensing device according to claim 5, wherein:
the third portion contacts the second base layer.

7. The image sensing device according to claim 5, wherein:
the second base layer extends between the first base layer and the light scattering suppression layer.

8. The image sensing device according to claim 4, wherein the peripheral region includes:
a light blocking region in which the light blocking layer is located; and
a pad region disposed at one side of the light blocking region and including a pad configured to transmit and receive electrical signals,
wherein
the first base layer is disposed in each of the pad region and the light blocking region.

9. The image sensing device according to claim 1, wherein:
the second base layer extends from the first base layer to the light scattering suppression layer; and
the second base layer includes a first top surface having a first height and a second top surface having a second height different from the first height,
wherein
the first top surface is formed to overlap the light scattering suppression layer in plan view; and
the second top surface is formed to overlap a space between the first base layer and the light scattering suppression layer in plan view.

10. The image sensing device according to claim 9, wherein:
the second base layer includes a third top surface having a third height in a region overlapping the first base layer in plan view,
wherein
the third height is different from the second height.

11. The image sensing device according to claim 1, wherein:
at least one of the first base layer and the second base layer includes at least one of an epoxy resin, a polyurethane resin, a polyester resin, an acrylic resin, and a silicone resin.

12. The image sensing device according to claim 11, wherein:
the first base layer includes a different material from the second base layer.

13. An image sensing device comprising:
an active pixel region including a first portion of a semiconductor layer that includes a photoelectric conversion region configured to convert incident light into electrical signals; and
a peripheral region disposed adjacent to the active pixel region, and including a light scattering suppression layer disposed on a second portion of the semiconductor layer extending from the first portion of the semiconductor layer and a base layer covering at least a portion of the light scattering suppression layer,
wherein
the base layer includes a groove portion recessed toward a top surface of the semiconductor layer.

14. The image sensing device according to claim 13, wherein:
the groove portion is located outside an edge portion of the light scattering suppression layer in plan view.

15. The image sensing device according to claim 14, wherein:
the groove portion is formed in a line shape extending along an outer surface of the edge portion of the light scattering suppression layer.

16. The image sensing device according to claim 13, wherein:
the base layer includes a first base layer spaced apart from the light scattering suppression layer, and a second base layer disposed on the first base layer,
wherein
the second base layer covers at least a portion of the light scattering suppression layer and the first base layer.

17. The image sensing device according to claim 13, wherein:
the peripheral region includes a pad region in which a pad configured to transmit and receive electrical signals is exposed from the semiconductor layer, and a light blocking region disposed between the pad region and the active pixel region; and
the groove portion is disposed in the light blocking region.

18. The image sensing device according to claim 13, wherein the peripheral region includes:
a pad region where a pad configured to transmit and receive electrical signals is exposed from the semiconductor layer;
a light blocking region disposed between the pad region and the active pixel region; and
a margin region located outside the pad region,
wherein
the groove portion is disposed in the margin region.

19. An image sensing device comprising:
a semiconductor layer including a photoelectric conversion region;
a light scattering suppression layer disposed on the semiconductor layer;
a first base layer disposed on the semiconductor layer and spaced apart from the light scattering suppression layer; and
a second base layer configured to cover the light scattering suppression layer and the first base layer,
wherein the second base layer includes:
a first region formed to overlap the light scattering suppression layer in plan view;
a second region formed to overlap the first base layer in plan view; and
a third region disposed between the first region and the second region,
wherein
the third region has a top surface recessed into the semiconductor layer.

20. The image sensing device according to claim 19, further comprising:
a color filter layer disposed on the semiconductor layer,
wherein
the second base layer includes a region extending from the first region onto a top surface of the color filter layer.
